(19) United States
(12) Patent Application Publication
(10) Pub. No.: US 2026/0096321 A1
(43) Pub. Date: Apr. 2, 2026

(54) DISPLAY PANEL AND METHOD OF MANUFACTURING DISPLAY PANEL

(71) Applicant: HKC CORPORATION LIMITED, SHENZHEN (CN)

(72) Inventors: Yao LI, SHENZHEN (CN); Zhonglin CAO, SHENZHEN (CN); Chuan WU, SHENZHEN (CN); Tien-Chun HUANG, SHENZHEN (CN); Haijiang YUAN, SHENZHEN (CN)

(73) Assignee: HKC CORPORATION LIMITED, SHENZHEN (CN)

(21) Appl. No.: 19/336,278

(22) Filed: Sep. 22, 2025

(30) Foreign Application Priority Data
Sep. 30, 2024 (CN) 202411400011.9

(51) Int. Cl. H10K 59/131; H10K 59/12; H10K 59/122; H10K 71/60

(52) U.S. Cl. CPC H10K 59/131; H10K 59/1201; H10K 59/122; H10K 71/60

(57) ABSTRACT

A display panel includes: a glass substrate, a silicon-based driver substrate, first bonding portions, and light emitting units. The glass substrate includes a first surface and a second surface opposite thereto. The glass substrate has first conductive through holes. The first surface has receiving grooves, each communicating with an end of a respective first conductive through hole near the first surface. The silicon-based driver substrate is arranged on the second surface of the glass substrate and comprises first bonding electrodes. Each first bonding electrode is at least partially embedded in a respective first conductive through hole. Each first bonding portion is received in a respectively first conductive through hole and is aligned to and bonded with a respective first bonding electrode. A surface of the first bonding portion away from the silicon-based driver substrate is lower than or flush with the first surface of the glass substrate.

### CROSS REFERENCE TO RELATED APPLICATIONS

The present application claims the priority of the Chinese patent application No. 202411400011.9, filed on Sep. 30, 2024, contents of which are incorporated herein by its entireties.

### TECHNICAL FIELD

Embodiments of the present disclosure relate to the technical field of displaying, and more specifically, to a display panel and a method of manufacturing a display panel.

### BACKGROUND

A monocrystalline silicon driver backplane is a driver substrate which takes a semiconductor device formed based on a complementary metal oxide semiconductor (CMOS) process as a driver unit. Compared to an active-matrix organic light emitting diode (AMOLED) panel which takes an amorphous silicon, a microcrystalline silicon, or a low-temperature polycrystalline silicon thin-film transistor as the backplane, the monocrystalline silicon driver backplane may have a higher carrier mobility. Therefore, a silicon-based organic light emitting diode (OLED) display panel may be a best performance display panel to be used in AR/VR products.

Currently, for the silicon-based OLED display panel, an externally-bound display chip may be integrated into the silicon-based driver backplane. A preparation method thereof is to perform evaporation to form the OLED device on the silicon-based driver substrate. Specific processes include: firstly performing deposition to form an anode, then preparing a pixel definition layer, and then performing deposition to successively form an organic light emitting layer and a cathode. In this way, smaller-sized pixel units may be prepared, and displaying finesse even better than retina may be achieved, such that a high resolution, high integration, lower power consumption, a small size, and a light weight, can be achieved.

However, direct evaporation to form the OLED device on silicon-based driver substrate may affect a silicon-based driver circuit, resulting in damage to the driver circuit, such that the driver circuit may be unusable, increasing manufacturing costs.

### SUMMARY

The present disclosure provides a display panel and a method of manufacturing the display panel, so as to solve the technical problem of circuit damages caused by direct evaporation to form the OLED device on silicon-based driver substrate.

In a first aspect, the present disclosure provides a display panel, including:
a glass substrate, including a first surface and a second surface opposite to the first surface, where the glass substrate has a plurality of conductive through holes extending from the first surface to the second surface; the plurality of the conductive through holes includes a plurality of first conductive through holes; the first surface of the glass substrate has a plurality of receiving grooves; each of the plurality of receiving grooves is communicated with an end of a respective one of the plurality of first conductive through holes near the first surface;
a silicon-based driver substrate, arranged on a side of the second surface of the glass substrate and including a plurality of first bonding electrodes; where each of the plurality of first bonding electrodes is at least partially embedded in a respective one of the plurality of first conductive through holes;
a plurality of first bonding portions, where each of the plurality of first bonding portions is received in a respectively one of the plurality of first conductive through holes and is aligned to and bonded with a respective one of the plurality of first bonding electrodes; a surface of each of the plurality of first bonding portions away from the silicon-based driver substrate is lower than or flush with the first surface of the glass substrate;
a plurality of light emitting units, arranged on the first surface of the glass substrate, where each of the plurality of light emitting units includes an anode electrode, an organic light emitting layer, and a cathode electrode that are stacked sequentially in a direction away from the glass substrate; each of the plurality of first bonding portions is electrically connected, through the respective first conductive through hole, to the anode electrode of a respective one of the plurality of light emitting units.

In a second aspect, the present disclosure provides a method of manufacturing a display panel, including:
providing a silicon-based driver substrate; where the silicon-based driver substrate includes a plurality of first bonding electrodes;
providing a glass substrate; where the glass substrate includes a first surface and a second surface opposite to the first surface; the glass substrate has a plurality of conductive through holes extending from the first surface to the second surface; the plurality of conductive through holes includes a plurality of first conductive through holes; the first surface of the glass substrate has a plurality of receiving grooves; each of the plurality of receiving grooves is communicated with an end of a respective one of the plurality of first conductive through holes near the first surface;
bonding a side of the second surface of the glass substrate to the silicon-based driver substrate; and embedding each of the plurality of first bonding electrodes into a respective one of the plurality of first conductive through holes;
filling a predetermined volume of a conductive material into each of the plurality of the first conductive through holes from the first surface to form a plurality of first bonding portions; where a surface of each of the plurality of first bonding portions away from the silicon-based driver substrate is lower than or flush with the first surface of the glass substrate; the predetermined volume is greater than or equal to a minimum volume required to fully fill each of the plurality of first conductive through holes and is less than or equal to a sum of a maximum volume required to fill a maximum volume required to fill each of the plurality of first conductive through hole and a volume of the respective receiving groove;
sequentially depositing anode electrodes, organic light emitting layers and cathode electrodes on the first surface of the glass substrate to form a plurality of light emitting units; where the plurality of first bonding portions are electrically connected to the anode electrodes through the plurality of first conductive through holes correspondingly.

In some embodiments, the providing a glass substrate includes:
forming, by a laser, a plurality of first modified zones extending from the first surface to the second surface on the glass substrate;
forming, by a laser, a plurality of second modified zones on the first surface; where, each of the plurality of second modified zones is connected to a respective one of the plurality of first modified zones; a surface of each of the plurality of second modified zones near the respective first modified zone is an inclined surface; an angle between the inclined surface and a central axis of the respective first modified zone may be less than 90°;
etching the plurality of first modified zones to form the plurality of first conductive through holes; and etching the plurality of second modified zones to form the plurality of receiving grooves.

### BRIEF DESCRIPTION OF THE DRAWINGS

FIG. 1 is a structural schematic view of a display panel according to a first embodiment of the present disclosure.

FIG. 2a is an enlarged view of a portion A of the display panel shown in FIG. 1.

FIG. 2b is an enlarged view of a portion B of the display panel shown in FIG. 1.

FIG. 2c is an enlarged view of a portion C of the display panel shown in FIG. 1.

FIG. 3 is a structural schematic view of a glass substrate of the portion shown in FIG. 2a.

FIG. 4 is a structural schematic view of a glass substrate of the display panel shown in FIG. 1.

FIG. 5 is a cross-sectional view of the display panel shown in FIG. 4, taken along a line A-A.

FIG. 6a is a structural schematic view of a receiving groove defined in the display panel according to an embodiment of the present disclosure.

FIG. 6b is another structural schematic view of the receiving groove defined in the display panel according to an embodiment of the present disclosure.

FIG. 6c is another structural schematic view of the receiving groove defined in the display panel according to an embodiment of the present disclosure.

FIG. 7 is a flow chart of a method of manufacturing the display panel according to an embodiment of the present disclosure.

FIG. 8 is a structural schematic view of a structure of an operation S1 in the method shown in FIG. 7.

FIG. 9 is a structural schematic view of a structure of an operation S2 in the method shown in FIG. 7.

FIG. 10 is a structural schematic view of a structure of an operation S3 in the method shown in FIG. 7.

FIG. 11 is a structural schematic view of a structure of an operation S4 in the method shown in FIG. 7.

FIG. 12 is a structural schematic view of a structure of an operation S5 in the method shown in FIG. 7.

FIG. 13 is a structural schematic view of a structure of an operation S21.

FIG. 14 is a structural schematic view of a structure of an operation S22.

### REFERENCE NUMERALS IN THE DRAWINGS

1—glass substrate; 2—silicon-based driver substrate; 3—first bonding portion; 4—light emitting unit; 5—conductor portion; 6—pixel definition layer; 7—second bonding portion; 8—encapsulation layer; 11—first surface; 12—second surface; 13—conductive through hole; 14—receiving groove; 15—opening; 41—anode electrode; 42—organic light emitting layer; 43—cathode electrode; 21—first bonding electrode; 22—silicon substrate; 23—driver circuit; 24—protection layer; 25—second bonding electrode; 131—first conductive through hole; 132—second conductive through hole; 140—second modified zone; 150—third modified zone; 1310—first modified zone.

### DETAILED DESCRIPTIONS

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

The present disclosure will be described in detail by referring to drawings and embodiments.

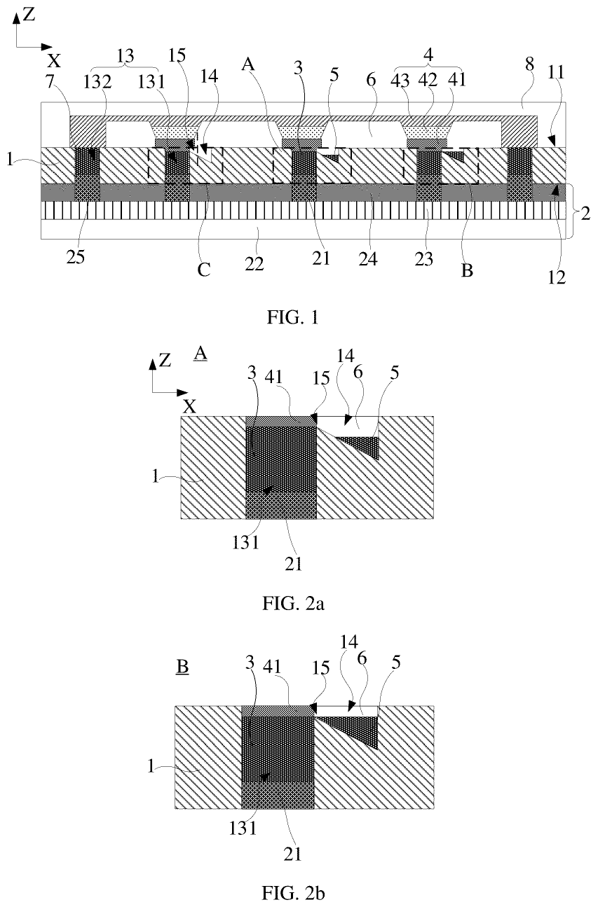

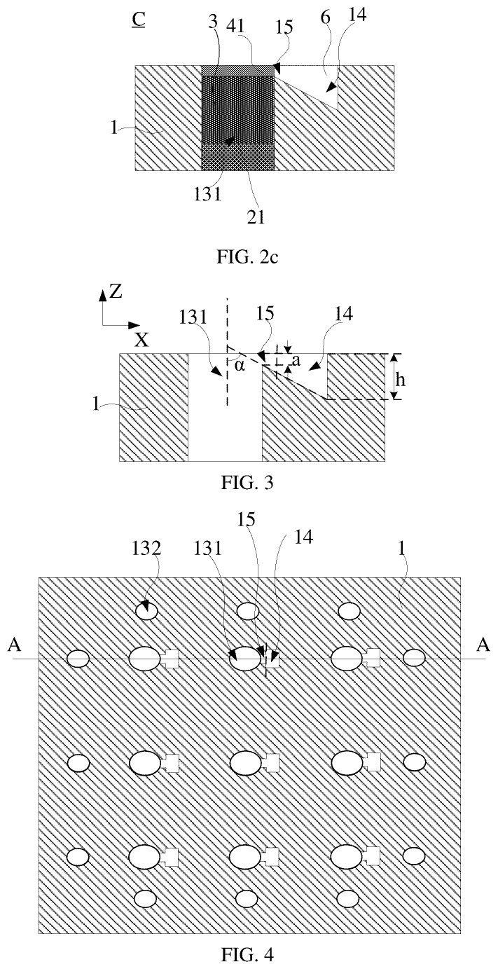

As shown in FIGS. 1 to 3, FIG. 1 is a structural schematic view of a display panel according to a first embodiment of the present disclosure; FIG. 2a is an enlarged view of a portion A of the display panel shown in FIG. 1; FIG. 2b is an enlarged view of a portion B of the display panel shown in FIG. 1; FIG. 2c is an enlarged view of a portion C of the display panel shown in FIG. 1; and FIG. 3 is a structural schematic view of a glass substrate of the portion shown in FIG. 2a. The present disclosure provides a display panel, the display panel may be an OLED display panel. The display panel may include a glass substrate 1, a silicon-based driver substrate 2, a plurality of first bonding portions 3, and a plurality of light emitting units 4.

As shown in FIGS. 1 and 3, the glass substrate 1 may include a first surface 11 and a second surface 12 opposite to the first surface 11. The glass substrate 1 may define a plurality of conductive through holes 13 extending from the first surface 11 to the second surface 12. The plurality of conductive through holes 13 may include a plurality of first conductive through holes 131. The first surface 11 of the glass substrate 1 may define a plurality of receiving grooves 14, and Each of the plurality of receiving grooves 14 may be communicated to an end of a respective one of the plurality of first conductive through hole 131 near the first surface 11. Each of the plurality of receiving grooves 14 may be disposed adjacent to the respective first conductive through hole 131. A conductor material may overflow from the end of each first conductive through hole 131 near the first surface 11 into the respective receiving groove 14. Specifically, each receiving groove 14 may extend from the first surface 11 of the glass substrate 1 in a direction towards the second surface 12.

As shown in FIG. 1, the silicon-based driver substrate 2 is arranged on a side of the second surface 12 of the glass substrate 1. The silicon-based driver substrate 2 may further include a plurality of first bonding electrodes 21. Each of the plurality of first bonding electrodes may be at least partially embedded in the respective first conductive through hole 131 and electrically connected to the respective first bonding portion 3, so as to control the light emitting unit 4 corresponding to the first bonding portion 3 to emit light. Specifically, each of the plurality of first bonding electrode 21 may be spaced apart from a side wall of the respective one of the plurality of first conductive through holes 131.

Specifically, the silicon-based driver substrate 2 may further include a silicon substrate 22 and a driver circuit 23 that are stacked with each other. The silicon substrate 22 refers to a substrate based on a monocrystalline silicon material. The driver circuit 23 may be electrically connected to the plurality of first bonding electrodes 21 to transmit anode drive signals to anode electrodes 41 through the plurality of first bonding portions 3. Specifically, the driver circuit 23 may include an active drive circuit 23 integrated on the monocrystalline silicon substrate 22 based on a complementary metal-oxide-semiconductor (CMOS) process. The driver circuit 23 may include a plurality of “3TIC” structures (three thin-film transistors and one capacitor) to enable each of the plurality of light emitting units 4 to be controlled independently and to display high-quality images.

The silicon-based driver substrate 2 may further include a display control circuit (not shown) electrically connected to the driver circuit 23. The display control circuit may control, via the driver circuit 23, the plurality of light emitting units 4 to display contents. The display control circuit may be an integrated circuit (IC) integrated on the silicon-based driver substrate 2.

As shown in FIG. 1 and FIG. 2a, each of the plurality of first bonding portions 3 may be received in the respective one of the plurality of first conductive through holes 131 and may be aligned and bonded to the respective one of the plurality of first bonding electrodes 21. The drive circuit 23 may transmit anode drive signals to the respective first bonding portion 3 received in the respective first conductive through hole 131 via the respective first bonding electrode 21. Specifically, the first bonding portion 3 may be formed by curing the conductive material in the first conductive through hole 131, and a surface of the first bonding portion 3 away from the silicon-based driver substrate 2 may be lower than or may flush with the first surface 11 of the glass substrate 1.

To be noted that, in one display panel, surfaces of all of the plurality of first bonding portions 3 may be lower than or flush with the first surface 11 of the glass substrate 1, instead of surfaces of a portion of the plurality of first bonding portions 3 being lower than the first surface 11 of the glass substrate 1 and surfaces of another portion of the plurality of first bonding portions 3 being flush with the first surface 11 of the glass substrate 1. That is, surfaces of all of the plurality of first bonding portions 3 away from the silicon-based driver substrate 2 in one display panel may be located at a same plane.

As shown in FIG. 1, the plurality of light emitting units 4 may be arranged on the first surface 11 of the glass substrate 1. Each of the plurality of light emitting units 4 may include an anode electrode 41, an organic light emitting layer 42, and a cathode electrode 43 that are stacked sequentially in a direction away from the glass substrate 1. The anode electrode 41 may be disposed on the first surface 11 of the glass substrate 1, and the organic light emitting layer 42 may be disposed on a surface of the anode electrode 41 away from the glass substrate 1. The cathode electrode 43 may be arranged on a side of the organic light emitting layer 42 away from the anode electrode 41. Cathode electrode 43 of the plurality of light emitting units 4 may cover organic light emitting layers 42 of the plurality of light emitting units 4 to form one integral common cathode. The anode electrode 41 and the cathode electrode 43 may respectively transmit the anode drive signals and cathode drive signals to the organic light emitting layer 42 to drive the organic light emitting layer 42 to emit light. Each of the plurality of first bonding portions 3 may be electrically connected, through the respective first conductive through hole 131, to the anode electrode 41 of the respective light emitting unit 4, and the driver circuit 23 may transmit, through the respective first bonding portion 3, the anode drive signals to the anode electrode 41 of the respective light emitting unit 4.

In some embodiments, the plurality of light emitting units 4 may include light emitting units 4 emitting light in different colors, such as a red light emitting unit 4, a green light emitting unit 4, and a blue light emitting unit 4, such that color displaying may be achieved. Specifically, a color of light emit from each light emitting unit 4 may be determined by a light emitting color of the organic light emitting layer 42 in the light emitting unit 4. Alternatively, in some embodiments, the plurality of light emitting units 4 may emit light in a same color, such as white, red, green, blue, or other colors, which may be determined according to the actual needs. For example, each of the plurality of light emitting units 4 may emit light in white, and grayscaled displaying may be achieved by controlling light brightness of the plurality of light emitting units 4. Alternatively, color-resistant layers may be arranged above the plurality of light emitting units 4 to achieve color displaying. For example, the plurality of light emitting units 4 may be blue light emitting units, red quantum dot layers may be arranged above a portion of the plurality of light emitting unit 4, and green quantum dot layers may be arranged above another portion of the plurality of light emitting unit 4. In this way, color displaying may be achieved.

Since the plurality of light emitting units 4 and the plurality of first bonding portions 3 are respectively on two opposite surfaces of the glass substrate 1, each of the plurality of first bonding portions 3 may be electrically connected, through the respective first conductive through hole 131, to the anode electrode 41 of the respective light emitting unit 4. In this way, the plurality of light emitting units 4 may be electrically connected to the silicon-based driver substrate 2, and the silicon-based drive substrate 2 may drive the plurality of light emitting units 4 to emit light. In this way, the plurality of light emitting units 4 may not be prepared directly on the silicon-based driver substrate 2, and damage to the pixel driver circuit 23, caused by directly preparing the plurality of light emitting units 4 on the silicon-based driver substrate 2, may be avoided, and the product yield may not be affected.

Any ordinary skilled person in the art shall understand that, the conductive material may be filled into the plurality of first conductive through holes 131 to form the plurality of first bonding portions 3. Heights of the plurality of first bonding electrodes 21 embedded in the plurality of first conductive through holes 131 may have deviations to each other. Therefore, when a same volume of the conductive material is filled into each of the plurality of first conductive through holes 131, heights of the plurality of first bonding portions 3 may have deviations to each other. The deviations in the heights of the plurality of first bonding portions 3 may result in the anodes arranged on the plurality of first bonding portions 3 to have reduced flatness. Therefore, light emitting brightness of the plurality of light emitting units 4 may be affected.

In the present embodiment, the plurality of receiving grooves 14 communicated to the plurality of first conductive through holes 131 may be defined in the first surface 11 of the glass substrate 1 facing towards the plurality of light emitting units 4. In this way, during a process of filling the conductive material into the plurality of first conductive through holes 131 to form the plurality of first bonding portions 3, a volume of the conductive material may be increased to a certain extent. In this way, it is ensured that the conductive material may fully fill each of the plurality of first conductive through holes 131, and any excessive conductive material may overflow from the first conductive through hole 131 to the receiving groove 14. In this way, it is ensured that surfaces of the plurality of first bonding portions 3 facing the anode electrodes 41 may be even, such that flatness of surfaces of the anodes may be ensured. Therefore, reflective angles and the reflectivities of light, which is emitted from total reflective layers of anodes to organic light emitting layers 42 of all of the plurality of light emitting units, may be consistent to each other, such that the light emitting brightness of the plurality of light emitting units 4 may be improved effectively.

As shown in FIG. 4 and FIG. 5, FIG. 4 is a structural schematic view of the glass substrate of the display panel shown in FIG. 1; and FIG. 5 is a cross-sectional view of the display panel shown in FIG. 4, taken along a line A-A. In an embodiment, each first conductive through hole 131 and the respective receiving groove 14 may have a common side wall, and the common side wall may have an opening 15. The receiving groove 14 may be communicated to the first conductive through hole 131 through the opening 15. During manufacturing the display panel, when filling the conductive material into the first conductive through hole 131, the excessive conductive material may overflow into the receiving groove 14 through the opening 15, such that the first bonding portion 3 may be completely received in the first conductive through hole 131.

The receiving groove 14 may be arranged on a side of the first conductive through hole 131 along a first direction X perpendicular to a stacking direction Z. A side wall between the first conductive through hole 131 and the receiving groove 14 may serve as the common side wall. The opening 15 may be defined in the first surface 11 of the glass substrate 1 and may be arranged on the common side wall between the receiving groove 14 and the first conductive through hole 131. Specifically, the opening 15 extends from the first surface 11 of the glass substrate 1 along the direction perpendicular to the glass substrate 1 towards the silicon-based driver substrate 2, such that a recessed structure may be formed in the common side wall between the first conductive through hole 131 and the receiving groove 14.

Specifically, the surface of the first bonding portion 3 away from the silicon-based driver substrate 2 may be lower than the first surface 11 of the glass substrate 1, such that the first bonding portion 3 is prevented from protruding out of the first conductive through hole 131, and therefore, surfaces of the subsequently-prepared anode electrodes 41 may be prevented from being uneven, and a reflection effect may not be affected. At the same time, the surface of the first bonding portion 3 away from the silicon-based driver substrate 2 may be flush with a side edge of the opening 15 away from the first surface 11. That is, the surface of the first bonding portion 3 away from the silicon-based driver substrate 2 may be flush with a bottom surface of the recessed structure defined in the common side wall. In this way, a height of the first bonding portion 3 may be prevented from being excessively low, and therefore, surfaces of the subsequently-prepared anode electrodes 41 may be prevented from being uneven, and the reflection effect may not be affected.

As shown in FIG. 3, further, a distance a between the side edge of the opening 15 away from the first surface 11 and the first surface 11 may be less than or equal to 50 Å. That is, a depth of the recessed structure may be less than or equal to 50 Å. Therefore, a maximum volume that can be received in the receiving groove 14 may not be reduced due to the opening 15 being excessively large, such that functioning of the receiving groove 14 may not be affected. Furthermore, the height of the first bonding portion received in the first conductive through hole 131 may not be excessively low, such that the anode electrode 41 can fully fill the remaining space of the first conductive through hole 131. Specifically, the distance a between the side edge of the opening 15 away from the first surface 11 and the first surface 11 may be in any value of 0 Å, 10 Å, 20 Å, 30 Å, 40 Å, or 50 Å. When the a is 0 Å, the receiving groove 14 may be directly communicated to the first conductive through hole 131 through the first surface 11.

As shown in FIG. 3, in an embodiment, a sidewall surface of the receiving groove 14 near the first conductive through hole may be an inclined surface to facilitate the excessive conductive material to flow into the receiving groove 14 from the first conductive through hole 131. In some embodiments, the bottom surface of the opening 15 may also be an inclined surface and may be in a same plane as the sidewall surface of the receiving groove 14 near the first conductive through hole 131, such that the excessive conductive material may be facilitated to flow from the first conductive through hole 131 through the opening 15 into the receiving groove 14. An angle α between the inclined surface and a central axis of the first conductive through hole 131 may be less than 90°. Specifically, the angle α between the inclined surface and the central axis of the first conductive through hole 131 may be in any value of 10°, 30°, 45°, 60°, or 75°.

Further, a maximum depth h of the receiving groove 14 may be greater than the distance a between the side edge of the opening 15 away from the first surface 11 and the first surface 11. In this way, it is ensured that the sidewall surface of the receiving groove 14 near the first conductive through hole 131 may be the inclined surface, and in addition, the conductive material that flows into the receiving groove 14 may be prevented from flowing reversely toward the first conductive through hole 131.

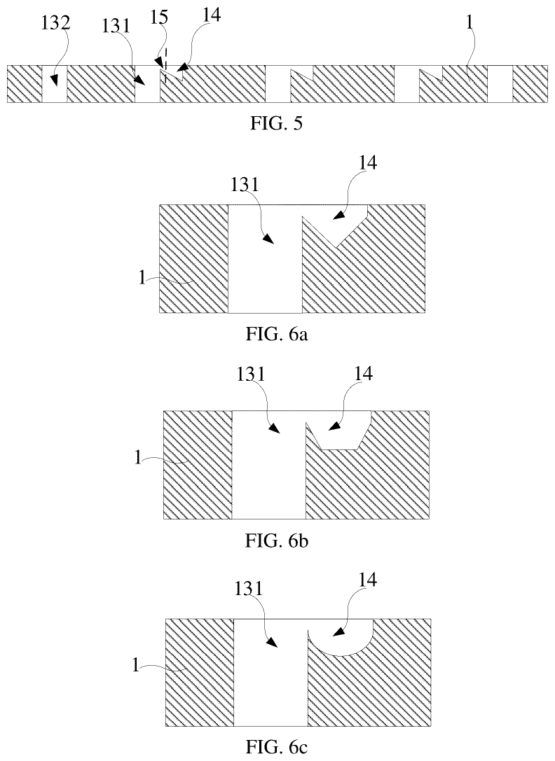

Specifically, as shown in FIGS. 6a-6c, structural schematic views of the receiving groove 14 in the display panel provided by some embodiments of the present disclosure are shown. In some embodiments, a cross section of the receiving groove 14 may be, in any of: triangular, trapezoidal, or circular, as long as the sidewall surface of the receiving groove 14 near the first conductive through hole 131 is the inclined surface.

As shown in FIGS. 2a-2b, in an embodiment, a conductor portion 5 may be received in the receiving groove 14. A material of the conductor portion 5 may be the same as a material of the first bonding portion 3. It is understood that the excessive conductive material overflow from the first conductive through hole 131 into the receiving groove 14, and the conductive material inside the receiving groove 14 may be cured to form the conductor portion 5. In this way, a side surface of first bonding portion 3 facing the anode electrode 41 may not exceed the bottom surface of the opening 15, such that the side surface of the first bonding portion 3 facing the anode electrode 41 may be flush to the bottom surface of the opening 15.

In an embodiment, when volumes of the conductive material overflowing from the plurality of first conductive through holes 131 into the respective plurality of receiving grooves 14 are different from each other, sizes of conductor portions 5 received in the plurality of receiving grooves 14 may be different from each other. Specifically, as shown in FIG. 2a, when the volume of the conductive material overflowing from each first conductive through hole 131 is relatively small, a side surface of the conductor portion 5 away from the silicon-based driver substrate 2 may be lower than the surface of the first bonding portion 3 away from the silicon-based driver substrate 2. That is, the side surface of the conductor portion 5 away from the silicon-based driver substrate 2 may be lower than the side edge of the opening 15 away from the first surface 11.

As shown in FIG. 2b, when the volume of the conductive material overflowing from each first conductive through hole 131 is relatively large, the side surface of the conductor portion 5 away from the silicon-based driver substrate 2 may be flush with the surface of the first bonding portion 3 away from the silicon-based driver substrate 2. That is, the side surface of the conductor portion 5 away from the silicon-based driver substrate 2 may be flush with the side edge of the opening 15 away from the first surface 11.

As shown in FIG. 2c, in an embodiment, the conductive material may just fully fill the first conductive through hole 131 and no conductive material overflows into the receiving groove 14. In this case, no conductor portion 5 is received in the receiving groove 14, the side surface of the first bonding portion 3 facing the anode electrode 41 may be just flush with the side edge of the opening 15 away from the first surface 11.

As shown in FIG. 1, a pixel definition layer 6 may be arranged on the first surface 11 of the glass substrate 1. The pixel definition layer 6 may protrude from the glass substrate 1 and enclose to form a plurality of pixel receiving regions (not shown in the drawings). Each of the plurality of light emitting units 4 may be received in a respective one of the plurality of pixel receiving regions. The plurality of pixel receiving regions may be in one-to-one correspondence with the plurality of first conductive through holes 131. Specifically, the anode electrode 41 may be received in the respective one pixel receiving region, and the pixel definition layer 6 covers an edge of the anode electrode 41, preventing anode electrodes 41 of adjacent two light emitting units 4 of the plurality of light emitting units 4 from being in contact with each other, such that crosstalk of signals may be prevented. At least a portion of the pixel definition layer 6 may completely cover the conductor portion 5 and fills the receiving groove 14, so as to insulate the conductor portion 5, preventing the conductor portion 5 from being in contact with the anode electrode 41, such that signal transmission may not be affected.

A distance b between a side edge of the first conductive through hole 131 away from the receiving groove 14 and the pixel definition layer 6 adjacent to the instant first conductive through hole 131 may be greater than or equal to 0. That is, the anode electrode 41 may cover only the surface of the first bonding portion 3, or may cover a portion of a surface of the glass substrate 1 located at a side of the first conductive through hole 131 away from the receiving groove 14. Specifically, the b may be in any value of 50 Å, 100 Å, 150 Å, 200 Å, and 250 Å.

The silicon-based driver substrate 2 may further include a protection layer 24 arranged on a side near the glass substrate 1. At least a portion of each first bonding electrode 21 may be embedded in the protection layer 24. The protection layer 24 may protect the driver circuit 23 from being corroded by external water vapor. A material of the protection layer 24 may be an inorganic insulating material, such as silicon dioxide, silicon nitride, or silicon nitride oxide. The first bonding electrode 21 may protrude from the protection layer 24, and a portion of the first bonding electrode 21 protruding from the protection layer 24 may be embedded in the first conductive through hole 131.

As shown in FIG. 1, in an embodiment, the plurality of conductive through holes 13 may further include a plurality of second conductive through holes 132 located at a circumferential periphery of the plurality of first conductive through holes 131. The display panel may further include a plurality of second bonding portions 7, each of the plurality of second bonding portions 7 may be at least partially received in a respective one of the plurality of second conductive through holes 132. Each of the plurality of second bonding portions 7 may be electrically connected, through the respective second conductive through hole 132, to the cathode electrode 43 to transmit cathode drive signals to the cathode electrode 43 of the respective light emitting unit 4. The silicon-based driver substrate 2 may further include a plurality of second bonding electrodes 25. The plurality of second bonding electrodes 25 may be in one-to-one aligned to and bonded with the plurality of second bonding portions 7. The silicon-based driver substrate 2 may transmit the cathode drive signals to the cathode electrode 43 through the plurality of second bonding electrodes 25 and the plurality of second bonding portions 7 to control the plurality of light emitting units 4 to emit light.

As shown in FIG. 1, in an embodiment, the glass substrate 1 is further arranged with an encapsulation layer 8 configured to protect the plurality of light emitting units 4 on the glass substrate 1, isolating the plurality of light emitting units 4 from external water and oxygen, and preventing invasion of the water and oxygen which may lead to failure of the plurality of light emitting units 4. Specifically, the encapsulation layer 8 may cover a surface of the cathode electrode 43 away from the anode electrodes 41 and laps over a surface of the glass substrate 1 that is not covered by the plurality of light emitting units 4.

According to the present disclosure, the display panel and the method of manufacturing the display panel are provided. The display panel includes the glass substrate 1, the silicon-base driver substrate 2, the plurality of first bonding portions 3, and the plurality of light emitting units 4. By arranging the plurality of light emitting units 4 and the plurality of first bonding portions 3 respectively on two opposite surfaces of the glass substrate 1, each of the plurality of first bonding portions 3 is electrically connected, through the respective first conductive through hole 131, to the anode electrode 41 of the respective light emitting unit 4, such that the light emitting units 4 are electrically connected to the silicon-based driver substrate 2, and the silicon-based driver substrate 2 may drive the plurality of light emitting units 4 to emit light. In this way, the plurality of light emitting units 4 may not be prepared directly on the silicon-based driver substrate 2, damage to the pixel driver circuit 23, caused by directly preparing the light emitting units 4 on the silicon-based driver substrate 2, may be prevented, such that a product yield may not be affected. Further, the plurality of receiving grooves 14, communicated to the plurality of first conductive through holes 131, are defined in the first surface 11 of the glass substrate 1 facing the plurality of light emitting units 4. Therefore, during a process of filling the conductive material into the plurality of first conductive through holes 131 to form the plurality of first bonding portions 3, a volume of the conductive material filled into the conductive through holes may be increased to a certain extent to ensure that the conductive material can fully fill the each of the plurality of first conductive through holes 131, and any excessive conductive material may flow from the plurality of first conductive through holes 131 to the plurality of receiving grooves 14. In this way, surfaces of the plurality of first bonding portions 3 facing the anode electrodes 41 may be flat, so as to ensure that flatness of surfaces of the anodes 41 may be improved. In this way, reflective angles and reflectivities of light, which is emitted from total reflective layers in all anodes to the organic light emitting layers 42, are consistent to each other, such that light emitting brightness of the plurality of light emitting units may be effectively improved.

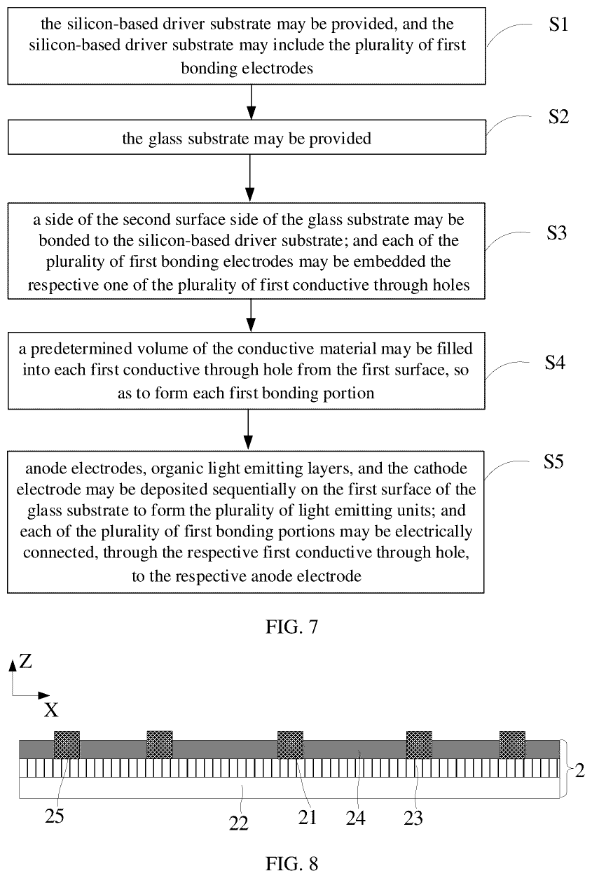

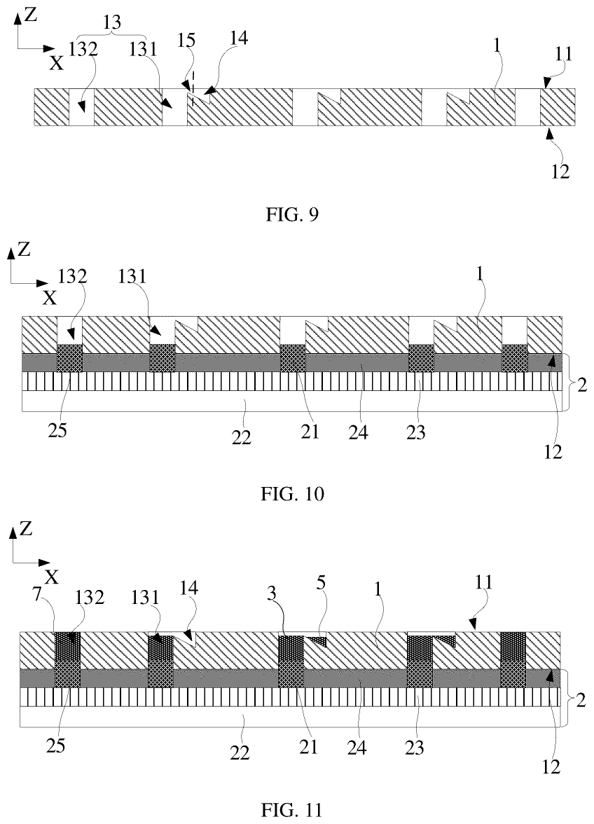

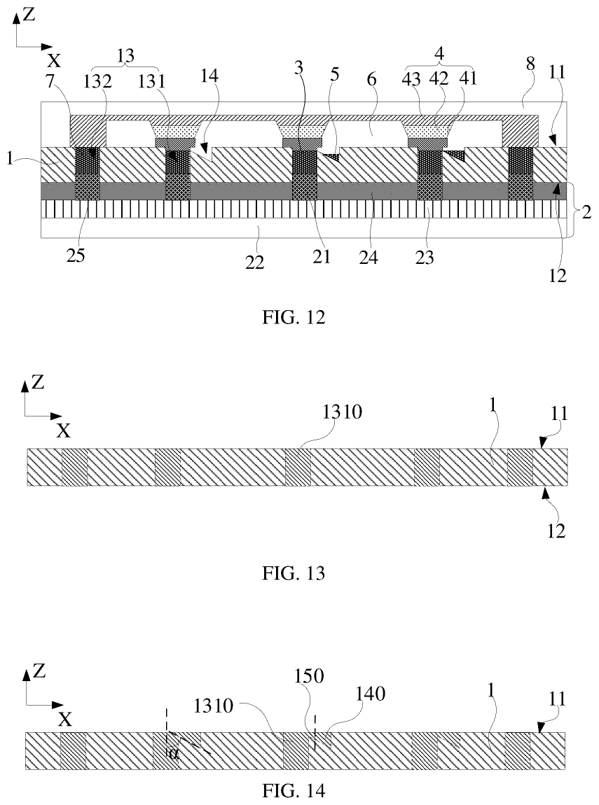

As shown in FIGS. 7 to 12, FIG. 7 is a flow chart of the method of manufacturing the display panel according to an embodiment of the present disclosure; FIG. 8 is a structural schematic view of a structure of an operation S1 in the method shown in FIG. 7; FIG. 9 is a structural schematic view of a structure of an operation S2 in the method shown in FIG. 7; FIG. 10 is a structural schematic view of a structure of an operation S3 in the method shown in FIG. 7; FIG. 11 is a structural schematic view of a structure of an operation S4 in the method shown in FIG. 7; and FIG. 12 is a structural schematic view of a structure of an operation S5 in the method shown in FIG. 7. The present disclosure further provides the method of manufacturing the display panel as described in any of the above embodiments. As shown in FIG. 7, the method may include following operations.

In an operation S1, the silicon-based driver substrate may be provided, and the silicon-based driver substrate may include the plurality of first bonding electrodes.

Specifically, as shown in FIG. 8, the silicon substrate 22 may be prepared based on the monocrystalline silicon material, and the driver circuit 23 may be prepared on the silicon substrate 22. By preparing the driver circuit 23 on the silicon substrate 22, the plurality of light emitting units 4 and the silicon-based driver substrate 2 are prepared separately, a preparing efficiency may be improved. Furthermore, by taking the silicon substrate 22 as a substrate for the silicon-based driver substrate 2, advantages of the silicon-based driver substrate 2 may be retained.

The conductive material may be deposited and patterned on a side surface of the driver circuit 23 away from the silicon substrate 22 to form the plurality of first bonding electrodes 21 and the plurality of second bonding electrodes 25. Each of the plurality of first bonding electrodes 21 and each of the plurality of second bonding electrodes 25 may be electrically connected to the driver circuit 23. In this way, the driver circuit 23 may transmit anode drive signals through the plurality of first bonding electrodes 21, and transmit the cathode drive signals through the plurality of second bonding electrodes 25.

An insulating material may be deposited on the side surface of the driver circuit 23 away from the silicon substrate 22 to form the protection layer 24 to protect the driver circuit 23. A plurality of through holes may be defined in the protection layer 24 at positions corresponding to the plurality of first bonding electrodes 21 and the plurality of second bonding electrodes 25 to enable the plurality of first bonding electrodes 21 and the plurality of second bonding electrodes 25 to be exposed through the plurality of through holes. That is, the plurality of first bonding electrode 21 and the plurality of second bonding electrode 25 may all be embedded in the plurality of first through holes defined in the protection layer 24. The plurality of first bonding electrodes 21 and the plurality of second bonding electrodes 25 may protrude from a surface of the protection layer 24 away from the silicon substrate 22.

In an operation S2, the glass substrate may be provided.

Specifically, as shown in FIG. 9, the glass substrate 1 may include the first surface 11 and the second surface 12 opposite to the first surface 11. Specifically, a surface located at a light-output side of the display panel may be the first surface 11, and the other surface opposite to the first surface may be the second surface 12. The glass substrate 1 may have the plurality of conductive through holes 13 extending from the first surface 11 to the second surface 12. In an implementation, the plurality of conductive through holes may be formed in the glass substrate 1 based on a laser-induced etching process. The plurality of conductive through holes may include the plurality of first conductive through holes 131 and the plurality of second conductive through holes 132. The first surface 11 of the glass substrate 1 may have the plurality of receiving grooves 14, each of the plurality of receiving grooves 14 may be communicated to the end of the respective first conductive through hole 131 near the first surface 11. The conductive material may overflow from the end of the first conductive through hole 131 near the first surface 11 into the respective receiving groove 14.

Compared to the silicon substrate 22, the glass substrate 1, which is used as the substrate, may have better insulating performance, and therefore, an oxidized insulating layer may not need to be formed on a hole wall of the conductive through hole 13, and a specialized holding technique for thin wafers may not needed, such that manufacturing costs may be reduced. In addition, due to the better insulating performance of the glass substrate 1, electromagnetic coupling effects may be generated during transmitting signals, an insertion loss and crosstalk of signals may be reduced effectively, ensuring integrity of signals. In addition, compared to silicon through holes, through holes in glass may provide excellent high-frequency electrical characteristics, have low costs, may be achieved by performing simple processes, and may be highly mechanically stable.

As shown in FIGS. 13-14, FIG. 13 is a structural schematic view of a structure of an operation S21; and FIG. 14 is a structural schematic view of a structure of an operation S22. In an implementation, the operation S2 may include following operations.

In an operation S21, a plurality of first modified zones extending from the first surface towards the second surface may be formed, by a laser, on the glass substrate.

Specifically, as shown in FIG. 13, the laser may irradiate positions on the glass substrate 1 where the plurality of first conductive through holes 131 are to be formed to form the plurality of first modified zones 1310 extending from the first surface 11 to the second surface 12 of the glass substrate 1.

In an operation S22, a plurality of second modified zones may be formed on the first surface by the laser. Each of the plurality of second modified zones may be connected to a respective one of the plurality of first modified zones, and a surface of each second modified zone near the respective first modified zone may be an inclined surface, an angle between the inclined surface and a central axis of the first modified zone may be less than 90°.

Specifically, as shown in FIG. 14, predetermined positions of the first surface 11 of the glass substrate 1 may be irradiated by the laser to form the plurality of second modified zones 140 adjacent to the plurality of first modified zones 1310 at a middle portion of the display panel. A side of each first modified zone 1310 along the first direction X may be connected to a side of the respective second modified zone 140 along the first direction X.

In an implementation, the glass substrate 1 may be translated along the first direction X, and an irradiation time length may be gradually increased or decreased, such that the side surface of each second modified zone 140 adjacent to the respective first modified zone 1310 may be the inclined surface. Therefore, the excessive conductive material may be facilitated to overflow from the first conductive through hole 131 into the receiving groove 14 during subsequent manufacturing processes. Specifically, the angle α between the inclined surface and the central axis of the first modified zone 1310 may be less than 90°; and specifically, the angle α between the inclined surface and the central axis of the first conductive through hole 131 may be in any value of 10°, 30°, 45°, 60°, or 75°.

Further, a portion of the first surface 11 of the glass substrate 1 disposed between the first modified zone 1310 and the second modified zone 140 may be irradiated by the laser to form a third modified zone 150 connecting each first modified zone 1310 with the respective second modified zone 140.

In an operation S23, the plurality of first modified zones may be etched to form the plurality of first conductive through holes; and the plurality of second modified zones may be etched to form the plurality of receiving grooves.

Specifically, as shown in FIG. 14 and FIG. 9, the plurality of first modified zones 1310 and the plurality of second modified zones 140 may be etched by an etching solution, so as to form the plurality of first conductive through holes 131 penetrating the glass substrate 1 at positions where the plurality of first modified zones 1310 are located, and to form the plurality of receiving grooves 14 at positions where the plurality of second modified zones 140 are located. Each of the plurality of receiving grooves 14 may be connected to an end of the respective first conductive through hole 131 near the first surface 11. In this way, during subsequent processes, the excessive conductive material may overflow from the first the plurality of conductive through holes 131 into the plurality of receiving grooves 14.

Further, the etching solution may further etch the third modified zone 150 to form the opening 15 connecting the first conductive through hole 131 to the receiving groove 14. Therefore, the excessive conductive material may flow from the first conductive through hole 131 into the receiving groove 14 through the opening 15.

In an operation S3, a side of the second surface side of the glass substrate may be bonded to the silicon-based driver substrate; and each of the plurality of first bonding electrodes may be embedded the respective one of the plurality of first conductive through holes.

Specifically, as shown in FIG. 10, a side of the silicon-based driver substrate 2 having the plurality of first bonding electrodes 21 may be bonded to the side of the second surface 12 of the glass substrate 1; and a portion of each first bonding electrode 21 protruding out of the protection layer 24 may be embedded in the respective first conductive through hole 131. In this way, the driver circuit 23 may transmit the anode drive signals through the first conductive through holes 131. The plurality of first bonding electrodes 21 embedded in the plurality of first conductive through holes 131 may not have a same height.

Each of the plurality of second bonding electrodes 25 may be embedded in a respective one of the plurality of second conductive through holes 132, enabling the driver circuit 23 to transmit the cathode drive signals through the plurality of second conductive through holes 132.

In an operation S4, a predetermined volume of the conductive material may be filled into each first conductive through hole from the first surface, so as to form each first bonding portion.

Specifically, as shown in FIG. 11, the predetermined volume of the conductive material may be filled into each first conductive through hole 131 from a side of the first surface 11 of the glass substrate 1.

Since heights of the plurality of first bonding electrodes 21 embedded in the plurality of first conductive through holes 131 may not be the same to each other, the predetermined volume may be greater than or equal to a minimum volume required to fully fill the first conductive through hole 131, such that the first bonding portion 3 may fully fill the first conductive through hole 131. The minimum volume may be a volume that is required to fully fill the first conductive through hole 131 in a case that the height of the first bonding electrode 21 embedded in the first conductive through hole 131 is maximized.

The predetermined volume may be less than or equal to a sum of the maximum volume required to fully fill the first conductive through hole 131 and a volume of the receiving groove 14. In this way, the excessive conductive material may be prevented from overflowing out of the receiving groove 14, and a surface of the first bonding portion 3 away from the silicon-based driver substrate 2 may be flat. The maximum volume may be a volume required to fully fill the first conductive through hole 131 when the height of the first bonding electrode 21 embedded in the first conductive through hole 131 is minimized.

The conductive material may be then cured, such that the conductive material in the first conductive through hole 131 may form the first bonding portion 3, and the conductive material in the receiving groove 14 may form the conductor portion 5. The surface of the first bonding portion 3 away from the silicon-based driver substrate 2 may be lower than and may flush with the first surface 11 of the glass substrate 1. In this way, a surface of the plurality of first bonding portions 3 away from the silicon-based driver substrate 2 may be flat.

In an operation S5, anode electrodes, organic light emitting layers, and the cathode electrode may be deposited sequentially on the first surface of the glass substrate to form the plurality of light emitting units; and each of the plurality of first bonding portions may be electrically connected, through the respective first conductive through hole, to the respective anode electrode.

Specifically, as shown in FIG. 12, the conductive material may be deposited on the first surface 11 of the glass substrate 1 and patterned to form the plurality of anode electrodes 41 that are spaced apart from each other; and the plurality of anode electrodes 41 may completely cover the plurality of first conductive through holes 131, such that each of the plurality of anode electrodes 41 may be electrically connected, through a respective one of the plurality of first conductive through holes 131, to a respective one of the plurality of first bonding portions 3.

The pixel definition layer 6, the organic light emitting layers 42, and the cathode electrode 43 may be sequentially prepared on a side of the plurality of anode electrodes 41 away from the glass substrate 1 to form the plurality of light emitting units 4. The pixel definition layer 6 may be formed by patterning a photoresist on the first surface 11 of the glass substrate 1. Alternatively, the pixel definition layer 6 may be formed by patterning an inorganic material film layer. Formation of the pixel definition layer 6 may be determined according to the actual needs.

The pixel definition layer 6 may protrude from the glass substrate 1 and encloses to form the plurality of pixel receiving regions. The pixel definition layer 6 may cover the edges of the anode electrodes 41 to ensure that adjacent anode electrodes 41 do not contact each other. A portion of the surface of each anode electrode 41 may be exposed through the respective pixel receiving region, such that the organic light emitting layer 42 may be on the surface of the anode electrode 41 disposed in the pixel receiving region. Furthermore, at least a portion of the pixel definition layer 6 may fully cover the respective conductor portion 5 and fully fill the respective receiving groove 14 to insulate the conductor portion 5, preventing the conductor portion 5 from being in contact with the anode electrode 41, such that signal transmission may not be affected.

Different light emitting layer materials may be used for evaporation on surfaces of the plurality of anode electrodes 41 to form a plurality of organic light emitting layers 42 having different light emitting colors, such as a red light emitting layer, a green light emitting layer, and a blue light emitting layer. Alternatively, a white light emitting layer material may be used for evaporation to form the white light emitting layer; and subsequently, color filtering layers may be prepared to achieve colored displaying.

In an implementation, a cathode material may be deposited by evaporation or sputtering on the side of the organic light emitting layers 42 away from the glass substrate 1 to form the cathode electrode 43. Specifically, the cathode material may be deposited on each organic light emitting layer 42 and the pixel definition layer 6 and may be extended to be deposited above the plurality of second conductive through holes 132. The cathode material may then contact and may be electrically connected to the plurality of second bonding portions 7 through the plurality of second conductive through holes 132 to form one integral cathode electrode 43. In this way, integrity of the cathode drive signal may be improved, and a voltage drop may be reduced.

The present application provides the method of manufacturing the display panel the method includes the following. Firstly, the silicon-based driver substrate 2 is provided. The silicon-based driver substrate 2 includes the plurality of first bonding electrodes 21. The glass substrate 1 is provided, and the glass substrate 1 includes the first surface 11 and the second surface 12 opposite to the first surface 11. The glass substrate 1 has the plurality of conductive through holes 13 extending from the first surface 11 to the second surface 12. The plurality of conductive through holes 13 include the plurality of first conductive through holes 131. The first surface 11 of the glass substrate 1 has the plurality of receiving grooves 14. Each receiving groove 14 is communicated to the end of the respective first conductive through hole 131 near the first surface 11. A side of the second surface 12 of the glass substrate 1 is bonded to the silicon-based driver substrate 2. The plurality of first bonding electrodes 21 are embedded in the plurality of first conductive through holes 131 respectively. The predetermined volume of conductive material is filled into each first conductive through hole 131 from the first surface 11 to form the plurality of first bonding portions 3. The surface of the first bonding portion 3 away from the silicon-based driver substrate 2 is lower than or flush with the first surface 11 of the glass substrate 1. The predetermined volume is greater than or equal to the minimum volume required to fully fill the first conductive through hole 131, and less than or equal to the sum of the maximum volume required to fully fill the first conductive through hole 131 and the volume of the receiving groove 14. The anode electrodes 41, the organic light emitting layers 42, and the cathode electrode 43 are deposited sequentially on the first surface 11 of the glass substrate 1 to form the plurality of light emitting units 4. The plurality of first bonding portions 3 are electrically connected to the anode electrodes 41 through the plurality of first conductive through holes 131 respectively. According to the above method, damage to the pixel driver circuit 23, caused by directly preparing the plurality of light emitting units 4 on the silicon-based driver substrate 2, may be avoided, and the light emitting brightness of the plurality of light emitting units 4 may be improved effectively.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a glass substrate, comprising a first surface and a second surface opposite to the first surface, wherein the glass substrate has a plurality of conductive through holes extending from the first surface to the second surface; the plurality of the conductive through holes comprises a plurality of first conductive through holes; the first surface of the glass substrate has a plurality of receiving grooves;
each of the plurality of receiving grooves is communicated with an end of a respective one of the plurality of first conductive through holes near the first surface;
a silicon-based driver substrate, arranged on a side of the second surface of the glass substrate and comprising a plurality of first bonding electrodes; wherein each of the plurality of first bonding electrodes is at least partially embedded in a respective one of the plurality of first conductive through holes;
a plurality of first bonding portions, wherein each of the plurality of first bonding portions is received in a respectively one of the plurality of first conductive through holes and is aligned to and bonded with a respective one of the plurality of first bonding electrodes; a surface of each of the plurality of first bonding portions away from the silicon-based driver substrate is lower than or flush with the first surface of the glass substrate;
a plurality of light emitting units, arranged on the first surface of the glass substrate, wherein each of the plurality of light emitting units comprises an anode electrode, an organic light emitting layer, and a cathode electrode that are stacked sequentially in a direction away from the glass substrate; each of the plurality of first bonding portions is electrically connected, through the respective first conductive through hole, to the anode electrode of a respective one of the plurality of light emitting units.

2. The display panel according to claim 1, wherein each of the plurality of first conductive through holes and the respective receiving groove has a common side wall; the common side wall has an opening; the receiving groove is communicated to the respective first conductive through hole through the opening;
the surface of the first bonding portion away from the silicon-based driver substrate is lower than the first surface of the glass substrate and is flush with a side edge of the opening away from the first surface.

3. The display panel according to claim 2, wherein, surfaces of all of the plurality of first bonding portions away from the silicon-based driver substrate are lower than the first surface of the glass substrate.

4. The display panel according to claim 2, wherein, surfaces of all of the plurality of first bonding portions away from the silicon-based driver substrate are flush with the first surface of the glass substrate.

5. The display panel according to claim 2, wherein, a maximum depth of the receiving groove is greater than a distance between a side edge of the opening away from the first surface and the first surface.

6. The display panel according to claim 5, wherein, the distance between the side edge of the opening away from the first surface and the first surface is less than or equal to 50 Å.

7. The display panel according to claim 5, wherein the distance between the side edge of the opening away from the first surface and the first surface is less than or equal to 50 Å and is greater than and equal to 0 Å.

8. The display panel according to claim 7, wherein, when the distance between the side edge of the opening away from the first surface and the first surface is 0 Å, the receiving groove is communicated with the first conductive through hole via the first surface of the glass substrate.

9. The display panel according to claim 5, wherein a maximum depth of the receiving groove is greater than the distance between the side edge of the opening away from the first surface and the first surface.

10. The display panel according to claim 6, wherein, the opening extends from the first surface in a direction perpendicular to the glass substrate towards the silicon-based driver substrate to form a recess.

11. The display panel according to claim 10, wherein, the surface of each of the plurality of first bonding portions away from the silicon-based driver substrate is flush with a recess bottom surface of the recess.

12. The display panel according to claim 1, wherein, a sidewall surface of each of the plurality of receiving grooves near a side of the respective first conductive through hole is an inclined surface; an angle between the inclined surface and a central axis of the respective first conductive through hole is less than 90°.

13. The display panel according to claim 1, wherein, a conductor portion is received in at least one of the plurality of receiving grooves; a material of the conductor portion is the same as a material of the respective first bonding portion; a side surface of the conductor portion away from the silicon-based driver substrate is lower than or is flush with the surface of the respective first bonding portion away from the silicon-based driver substrate.

14. The display panel according to claim 13, wherein, each of the plurality of first bonding portions is made of a conductive material filled into the respective first conductive through hole; the respective receiving groove is configured to receive any excessive conductive material overflowing out of the first conductive through hole; and the conductor portion is made of the excessive conductive material.

15. The display panel according to claim 13, wherein, at least one of the plurality of receiving grooves is not arranged with any conductor portion.

16. The display panel according to claim 13, further comprising: a pixel definition layer, arranged on the first surface of the glass substrate; wherein the pixel definition layer protrudes from the glass substrate and encloses to form a pixel receiving region; the anode electrode is received in the pixel receiving region; and at least a portion of the pixel definition layer completely covers the conductor portion and fills the receiving groove.

17. A method of manufacturing a display panel, comprising:
providing a silicon-based driver substrate; wherein the silicon-based driver substrate comprises a plurality of first bonding electrodes;
providing a glass substrate; wherein the glass substrate comprises a first surface and a second surface opposite to the first surface; the glass substrate has a plurality of conductive through holes extending from the first surface to the second surface; the plurality of conductive through holes comprises a plurality of first conductive through holes; the first surface of the glass substrate has a plurality of receiving grooves; each of the plurality of receiving grooves is communicated with an end of a respective one of the plurality of first conductive through holes near the first surface;
bonding a side of the second surface of the glass substrate to the silicon-based driver substrate; and embedding each of the plurality of first bonding electrodes into a respective one of the plurality of first conductive through holes;
filling a predetermined volume of a conductive material into each of the plurality of the first conductive through holes from the first surface to form a plurality of first bonding portions; wherein a surface of each of the plurality of first bonding portions away from the silicon-based driver substrate is lower than or flush with the first surface of the glass substrate; the predetermined volume is greater than or equal to a minimum volume required to fully fill each of the plurality of first conductive through holes and is less than or equal to a sum of a maximum volume required to fill a maximum volume required to fill each of the plurality of first conductive through hole and a volume of the respective receiving groove;
sequentially depositing anode electrodes, organic light emitting layers and cathode electrodes on the first surface of the glass substrate to form a plurality of light emitting units; wherein the plurality of first bonding portions are electrically connected to the anode electrodes through the plurality of first conductive through holes correspondingly.

18. The method according to claim 17, wherein, the providing a glass substrate comprises:
forming, by a laser, a plurality of first modified zones extending from the first surface to the second surface on the glass substrate;
forming, by a laser, a plurality of second modified zones on the first surface; wherein, each of the plurality of second modified zones is connected to a respective one of the plurality of first modified zones; a surface of each of the plurality of second modified zones near the respective first modified zone is an inclined surface; an angle between the inclined surface and a central axis of the respective first modified zone may be less than 90°; and
etching the plurality of first modified zones to form the plurality of first conductive through holes; and etching the plurality of second modified zones to form the plurality of receiving grooves.

19. The method according to claim 17, wherein, each of the plurality of receiving grooves receives any excessive conductive material overflowing out of the respective first conductive through hole.

20. The method according to claim 18, wherein the inclined surface is formed by translating the glass substrate and by adjusting a laser irradiation time length.
